(19) United States
(12) Patent Application Publication
(10) Pub. No.: US 2026/0305377 A1
(43) Pub. Date: Oct. 1, 2026

(54) METAL FRAME CHIP EMBEDDED PACKAGING SUBSTRATE AND MANUFACTURING METHOD THEREOF

(71) Applicant: Zhuhai ACCESS Semiconductor Co., Ltd, Guangdong (CN)

(72) Inventors: XIANMING CHEN, Guangdong (CN); LEI FENG, Guangdong (CN); JINDONG FENG, Guangdong (CN); BENXIA HUANG, Guangdong (CN); JIANGJIANG ZHAO, Guangdong (CN); GAO HUANG, Guangdong (CN); ZHIJUN ZHANG, Guangdong (CN)

(21) Appl. No.: 19/705,976

(22) Filed: Jun. 12, 2026

Related U.S. Application Data
(62) Division of application No. 18/603,375, filed on Mar. 13, 2024.

(30) Foreign Application Priority Data
Mar. 14, 2023 (CN) 2023102473687

(51) Int. Cl. H10W 70/40; H10W 70/04; H10W 72/00; H10W 70/09; H10W 70/60

(52) U.S. Cl. CPC H10W 70/421; H10W 70/042; H10W 72/071; H10W 70/09; H10W 70/60

(57) ABSTRACT

A manufacturing method for a metal frame chip embedded packaging substrate includes preparing a metal plate, forming a metal frame surrounding a cavity by penetrating the metal plate, and selectively partially etching a first surface of the metal frame to form a first groove on the metal frame, embedding a chip in the cavity so that a patterned side of the chip faces the first surface, and laminating a dielectric layer on a second surface of the metal frame opposite the first surface, the dielectric layer covering a back side of the chip and filling the first groove, forming a blind hole and a window on the dielectric layer, and forming a first wiring layer on the first surface and a second wiring layer on the second surface, the first wiring layer being connected to a terminal of the chip.

### CROSS-REFERENCE TO RELATED APPLICATION AND CLAIM OF PRIORITY

This application is a divisional application of US Patent Application No. 18/603,375 filed on March 13, 2024, which claims priority to the benefit of Chinese Patent Application No. 2023102473687 filed on March 14, 2023, in the China Intellectual Property Office, the entire disclosure of which are incorporated herein by reference for all purposes.

### BACKGROUND

### TECHNICAL FIELD

The present application relates to the technical field of electronic component packaging, and in particular to a metal frame chip embedded packaging substrate and a manufacturing method thereof.

### BACKGROUND OF THE INVENTION

Among the existing technical solutions of a metal frame chip embedded packaging substrate, the most common practices are as follows: firstly, the frame for embedding the chip is prepared by etching or mechanical means, after filling the chip, the dielectric material is filled on both sides, then the electrical signal channel is opened by laser or the like, and finally the pattern is prepared by electroplating.

In the prior art, after the preparation of the metal frame is completed, due to the conductivity of the metal, subsequently when the electrical signal of the chip is led out, a double-sided lamination of dielectric material is necessary; for some products with light and thin thickness requirements, the dielectric material on both sides of the metal frame has a large influence on the thickness, and at the same time, the double-sided lamination of dielectric material will also make the process complicated and increase cost.

### SUMMARY

In view of this, the object of the present application is to provide a metal frame chip embedded packaging substrate and a manufacturing method thereof.

Based on the above-mentioned object, the present application provides a manufacturing method of a metal frame chip embedded packaging substrate, including:

preparing a metal plate;

forming a cavity penetrating the metal plate and a metal frame surrounding the cavity on the metal plate, and selectively partially etching a first surface of the metal frame to form a first groove on the metal frame;

embedding the chip in the cavity so that a patterned side of the chip faces the first surface, and laminating a dielectric layer on a second surface of the metal frame opposite the first surface, wherein the dielectric layer covers a back side of the chip and fills the first groove;

forming a blind hole and a window on the dielectric layer, the blind hole being configured to expose the second surface of the metal frame, and the window being configured to expose the back side of the chip;

forming a first wiring layer on the first surface and a second wiring layer on the second surface; wherein the second wiring layer is connected to the back side of the chip through a first conducting post formed by electroplating the window, and is connected to the metal frame through a second conducting post formed by electroplating the blind hole, wherein the first wiring layer is connected to a terminal of the chip.

The present application also provides a metal frame chip embedded packaging substrate, including: a metal frame and a cavity surrounded by the metal frame, and a chip embedded in the cavity;

wherein a first groove is formed on a first surface of the metal frame, and a metal thickness of the first groove is less than a thickness of the metal frame;

a patterned side of the chip faces the first surface, and a dielectric layer is formed on a second surface of the metal frame opposite the first surface, the dielectric layer covering a back side of the chip and filling the first groove;

a blind hole and a window are formed on the dielectric layer, the blind hole being configured to expose the second surface of the metal frame, and the window being configured to expose the back side of the chip;

a first wiring layer is formed on the first surface and a second wiring layer is formed on the second surface; wherein the second wiring layer is connected to the back side of the chip through a first conducting post formed by electroplating the window, and is connected to the metal frame through a second conducting post formed by electroplating the blind hole, wherein the first wiring layer is connected to a terminal of the chip.

It can be seen from the above that the present application provides a metal frame chip embedded packaging substrate and a manufacturing method thereof. By performing a single-sided plastic packaging dielectric layer on a metal frame, and further performing a height differential design on peripheral frames of the cavity, when a patterned side signal of the chip is led out, the electrical signal of the chip can be directly led out through a dielectric material filled on an edge of the metal frame with a low height, without a separate lamination of dielectric material, so as to achieve a differential wiring design and improve the wiring density, which can to a certain extent solve the problems of large packaging thickness, low wiring density, complex process and high material cost of the embedded device packaging substrate in the prior art.

### BRIEF DESCRIPTION OF THE DRAWINGS

In order to explain the technical solution of the present application or the related art more clearly, the following will briefly introduce the drawings which are used in the description of the embodiments or the related art; obviously, the drawings in the description below are merely embodiments of the present application, and it would have been obvious for a person of ordinary skill in the art to obtain other drawings according to these drawings without involving any inventive effort.

FIG. 1A shows a schematic diagram of a patterned side of an exemplary metal frame chip embedded packaging substrate of an embodiment of the present application;

FIG. 1B is a cross-sectional view of FIG. 1A in the direction AA’;

FIG. 1C is a cross-sectional view of FIG. 1A in the direction BB’;

FIGS. 2A-2H show schematic cross-sectional diagrams of intermediate structures of various steps of a manufacturing method of a metal frame chip embedded packaging substrate of an embodiment of the present application.

### DETAILED DESCRIPTION OF THE EMBODIMENTS

In order to make the object, technical solution and advantages of the present application more clear, the present application is described in further detail below in connection with specific embodiments and with reference to the accompanying drawings.

It should be noted that, unless otherwise defined, technical or scientific terms used in the embodiments of the present application shall have the ordinary meaning as understood by one of ordinary skill in the art to which the present application belongs. The use of the terms “first”, “second”, and the like in the embodiments of the present application does not denote any order, quantity, or importance, but rather is used to distinguish one element from another. The word “comprise” or “contain”, and the like, means that the elements or items preceding the word encompass the elements or items listed after the word and equivalents thereof, but do not exclude other elements or items. The word “connect” or “communicate”, and the like are not limited to physical or mechanical connections, but may include electrical connections, whether direct or indirect. The words “up”, “down”, “left”, “right”, etc. are only used to indicate a relative positional relationship, which may change accordingly when the absolute position of the object being described changes.

A pre-made frame plate is generally used in the current embedded device packaging substrate. An adhesive material is attached to a side of the frame plate, a chip is adhered by the adhesive material, and after packaging, the adhesive material is torn off then to add layers, and a dielectric layer needs to be laminated to a patterned side of the chip and then an electrical signal is led out. Therefore, the current embedded device packaging substrate has problems of large packaging thickness, low wiring density, complex process and high material cost.

Based on this, the embodiments of the present application provide a metal frame chip embedded packaging substrate and a manufacturing method thereof. By performing a single-sided plastic packaging dielectric layer on a metal frame, and further performing a height differential design on peripheral frames of the cavity, when a patterned side signal of the chip is led out, the electrical signal of the chip can be directly led out through a dielectric material filled on an edge of the metal frame with a low height, without a separate lamination of dielectric material, so as to achieve a differential wiring design and improve the wiring density, which can to a certain extent solve the problems of large packaging thickness, low wiring density, complex process and high material cost of the embedded device packaging substrate in the prior art.

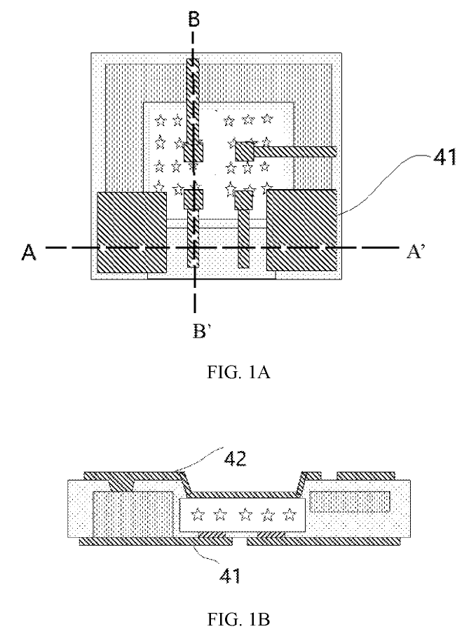

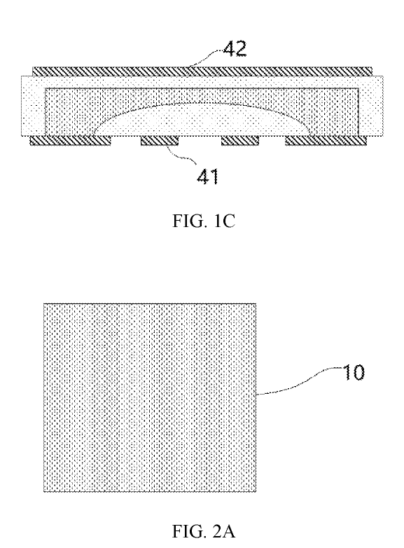

FIG. 1A shows a schematic diagram of a patterned side of an exemplary metal frame chip embedded packaging substrate of an embodiment of the present application. FIG. 1B is a cross-sectional view of FIG. 1A in the direction AA’; and FIG. 1C is a cross-sectional view of FIG. 1A in the direction BB’;

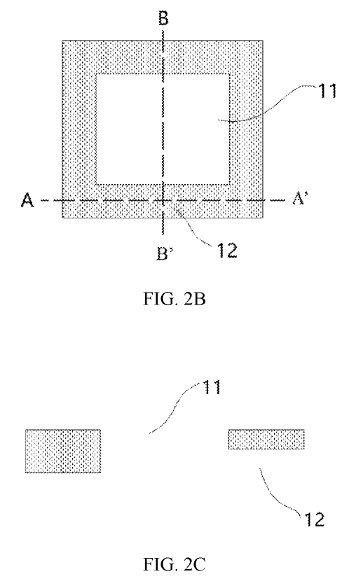

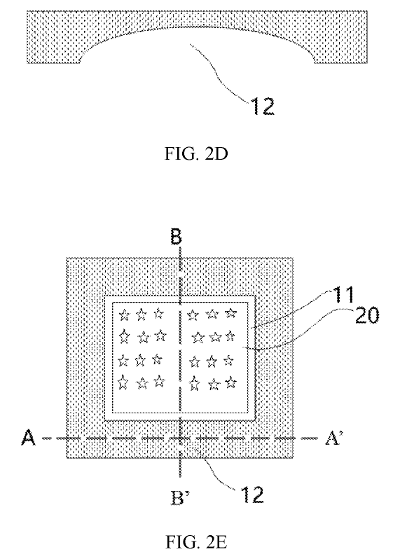

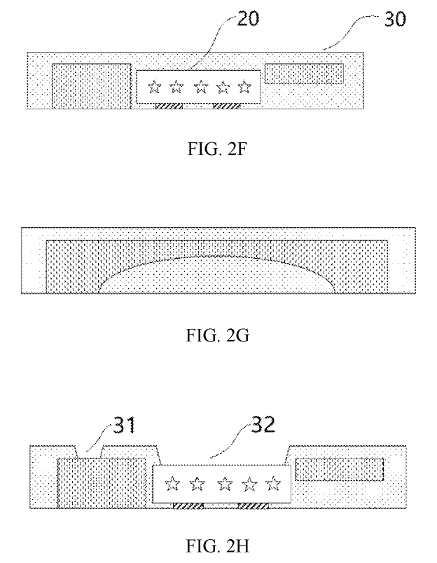

As shown in FIGS. 1A-1C and 2A-2H, the metal frame chip embedded packaging substrate may include: a metal frame 10 and a cavity 11 surrounded by the metal frame 10, and a chip 20 embedded in the cavity 11;

wherein a first groove 12 is formed on a first surface of the metal frame 10, and a metal thickness of the first groove 12 is less than a thickness of the metal frame 10;

a patterned side of the chip 20 faces the first surface, and a dielectric layer 30 is formed on a second surface of the metal frame 10 opposite to the first surface, the dielectric layer 30 covering a back side of the chip 20 and filling the first groove 12;

a blind hole 31 and a window 32 are formed on the dielectric layer 30, the blind hole 31 being configured to expose the second surface of the metal frame 10, and the window 32 being configured to expose the back side of the chip 20;

a first wiring layer 41 is formed on the first surface and a second wiring layer 42 is formed on the second surface; wherein the second wiring layer 42 is connected to the back side of the chip 20 through a first conducting post formed by electroplating the window 32, and is connected to the metal frame 10 through a second conducting post formed by electroplating the blind hole 31.

Wherein the first wiring layer 41 is connected to a terminal of the chip 20.

Wherein the metal frame 10 may be a copper plate (e.g. a pure copper plate) because it has good heat dissipation and support strength, etc. The thickness (i.e. height) of the metal frame 10 may be selected according to the design. Generally, the thickness of the metal frame 10 should be greater than the height of the embedded chip 20.

Wherein the cavity 11 may be understood as an opening through the metal frame 10. The dimensions of the cavity 11 should be greater than the dimensions of the embedded chip 20. For example, the length and width of the cavity 11 may each be greater than the length and width of the embedded chip 20. In this way, it is convenient to fill the dielectric material between the chip 20 and the cavity 11. The chip 20 has a patterned side and a back side separated by the height of the chip 20.

As shown in FIGS. 1B and 1C, the first groove 12 may be a partial area of the metal frame 10 surrounding the cavity 11. In this way, it is possible to form a height difference around the cavity 11, thereby forming a metal frame structure having a groove. After the groove is filled with a dielectric layer, it is possible to directly lead out chip terminals on the surface through wires without contacting the metal frame 10, so that a double-sided laminated dielectric layer is not required, thereby shortening the process time and further reducing the substrate thickness.

The first groove 12 may be provided at any position of the metal frame 10 as long as the surface wire thereof is prevented from contacting the metal frame 10. In some embodiments, the first groove 12 is provided on one frame of the metal frame 10, or grooves may be provided on a plurality of frames of the metal frame 10 around the cavity 11.

In some embodiments, the first groove 12 may be recessed from a first surface to a second surface of the metal frame 10, and the shape of the cross-section of the first groove 12 may be, for example, an arch or the like. The metal height of the first groove 12 may be 8 microns or more.

In some embodiments, the blind hole 31 may be opened at the metal frame 10 opposite the first groove 12. In this way, the stability of the connection of the second wiring layer 42 to the metal frame 10 may be improved.

In some embodiments, the dielectric layer 30 may be selected from an Ajinomoto Build-up Film (ABF) resin or a polypropylene (PP) resin. The dielectric layer 30 may be formed by laminating a dielectric material on the second surface of the metal frame 10 (i.e. the back side of the chip 20). The surface of dielectric layer 30 may be flush with the terminals of the patterned side of the chip 20. In this way, the thickness of the packaging substrate may be reduced as much as possible.

The first conducting post and the second conducting post mentioned in the present embodiment may each independently include at least one copper through-hole post as an IO channel to achieve conduction between layers. The size and/or shape of the multiple copper through-hole posts may be the same or different. The copper through-hole post may be a solid copper post or a hollow post plated with copper on the surface. Preferably, the conducting posts may include a plurality of copper through-hole posts as IO channels.

The embodiments of the present application provide a metal frame chip embedded packaging substrate. By performing a height differential design on peripheral frames of the cavity 11, when a patterned side terminal signal of the chip 20 is led out, the electrical signal of the chip 20 can be directly led out separately without contacting the metal frame 10 by directly passing through the dielectric layer filled on the first groove 12 with a low height, and no additional lamination of dielectric material is needed, so as to achieve a differential wiring design and improve the wiring density; at the same time, the patterned side of the chip 20 does not need to be laminated with a dielectric layer, and the overall substrate packaging thickness may be reduced.

FIGS. 2A-2H show schematic cross-sectional diagrams of intermediate structures of various steps of a manufacturing method of a metal frame chip embedded packaging substrate of an embodiment of the present application.

A manufacturing method of a metal frame chip embedded packaging substrate includes the following steps of:

preparing a metal plate (step (a)), as shown in FIG. 2A. Wherein the metal plate may be a copper plate (e.g. a pure copper plate). The thickness (i.e. height) of the metal plate may be selected according to the design. Generally, the thickness of the metal plate may be greater than the height of the embedded chip 20.

Next, forming a cavity 11 penetrating the metal plate and forming a metal frame 10 surrounding the cavity 11 on the metal plate (step (b)), and selectively partially etching a first surface of the metal frame 10 at the periphery of the cavity 11 to form a first groove 12, so that a height of the first groove 12 is different from that of the metal frame 10, as shown in FIGS. 2B to 2D. Wherein FIG. 2C is a cross-sectional view of FIG. 2B in the direction AA’; and FIG. 2D is a cross-sectional view of FIG. 2B in the direction BB’.

In some embodiments, the metal height of the first groove 12 is less than the height of the remaining area of the metal frame 10. Generally, the first groove 12 can be provided in the middle of the frame. The etching can be performed from a first surface (e.g. a bottom side) of the metal frame 10 to a second surface (e.g. a top side) of the metal frame 10. The shape of the first groove 12 may be a flat groove or the like. The metal height of the first groove 12 can be 8 microns or more.

In some embodiments, the metal height of the first groove 12 is not uniform, e.g. the cross-section of the first groove 12 may be arcuate or the like. In this way, it is possible to make the first groove 12 itself form a structure having a height difference.

Then, the chip 20 can be embedded in the frame 11 so that a patterned side of the chip 20 faces the first surface, and a dielectric layer 30 can be laminated on the back side of the chip 20 while filling the first groove 12 by the dielectric layer 30 so that the dielectric layer 30 is flush with the first surface of the metal frame 10 (step (c)), as shown in FIGS. 2E to 2G. Generally, the chip 20 may be adhered by attaching an adhesive material to a first surface of the metal frame 10, and then tearing off the adhesive material after the dielectric layer 30 is laminated on the back side of the chip 20.

Wherein the dielectric layer 30 may be selected from an Ajinomoto Build-up Film (ABF) resin or a polypropylene (PP) resin. The surface of the dielectric layer 30 may be flush with the first surface of the metal frame 10 and the terminals of the chip 20, while the dielectric layer 30 is formed on the second surface of the metal frame 10. The dielectric layer 30 is formed by laminating on the back side of the chip 20, the dielectric layer 30 may fill the gap between the chip 20 and the cavity 11, and fill the first groove 12. In this way, after the dielectric layer 30 is laminated on a single side, i.e. by filling the dielectric layer 30 in the first groove 12, subsequently, the electrical signal of the chip 20 may be led out directly without the need for separately laminating the dielectric material, facilitating subsequent differential wiring design and reducing substrate thickness, etc.

Next, a blind hole 31 and a window 32 can be formed on the dielectric layer 30, the blind hole 31 being configured to expose the second surface of the metal frame 10, and the window 32 being configured to expose the back side of the chip 20 (step (d)), as shown in FIG. 2H. Wherein there is no change in FIG. 2G after this step. Generally, the blind hole 31 and the window 32 can be formed by laser.

In some embodiments, the blind hole 31 can be opened at the metal frame 10 opposite the first groove 12.

Then, a first wiring layer 41 can be formed on the first surface of the metal frame 10, and a second wiring layer 42 can be formed on the surface of the dielectric layer 30 (step (e)), as shown in FIGS. 1A and 1B. Generally, the first wiring layer 41 and the second wiring layer 42 can be formed by first forming a seed layer, and then pattern electroplating and the like. FIG. 1A shows a schematic diagram of a patterned side of an exemplary metal frame chip embedded packaging substrate of an embodiment of the present application. FIG. 1B is a cross-sectional view of FIG. 1A in the direction AA’; and FIG. 1C is a cross-sectional view of FIG. 1A in the direction BB’;

As shown in FIG. 1B, the second wiring layer 42 is connected to the back side of the chip 20 through a first conducting post formed by electroplating the window 32, and is connected to the metal frame 10 through a second conducting post formed by electroplating the blind hole 31. In this way, the connection of the back side of the chip 20 to the metal frame 10 is achieved through the second wiring layer 42, so that the chip 20 can dissipate heat better through the metal frame 10. As shown in FIG. 1C, the first wiring layer 41 is connected to a terminal of the chip 20 to separately lead out the signals. Meanwhile, it is also possible to further dissipate heat by connecting the first wiring layer 41 and the second wiring layer 42 through the metal frame 10. In this way, it is possible to individually route a part of the wires of the first wiring layer 41 directly led out from the terminals of the chip 20 through the dielectric layer 30 filled on the first groove 12 without pressing the dielectric layer 30 on the patterned side of the chip 20 without contacting the metal frame 10, thereby increasing the wiring density while reducing the overall thickness of the substrate, etc.

Those of ordinary skill in the art will appreciate that the discussion of any embodiment above is merely exemplary and is not intended to imply that the scope of the present application, including the claims, is limited to these examples; combinations of features in the above embodiments or in different embodiments are also possible within the framework of the present application, the steps can be implemented in any order, and there are many other variations of the different aspects of the embodiments of the present application described above, which are not provided in detail for the sake of brevity.

In addition, well-known power/ground connections to integrated circuit (IC) chips and other components may or may not be shown in the provided figures for simplicity of illustration and discussion, and so as not to obscure the embodiments of the present application. Furthermore, devices may be shown in block diagram form in order to avoid obscuring the embodiments of the present application, and this also takes into account the fact that the details regarding the implementation of such block diagram devices are highly dependent upon the platform on which the embodiments of the present application are to be implemented (i.e. such details should be well within the understanding of those skilled in the art). Where specific details (e.g. circuits) are set forth in order to describe example embodiments of the present application, it will be apparent to those skilled in the art that the embodiments of the present application may be practiced without, or with variation of, these specific details. Accordingly, the description should be regarded as illustrative rather than restrictive.

While the present application has been described in conjunction with specific embodiments thereof, it is evident that many alternatives, modifications, and variations will be apparent to those skilled in the art in light of the foregoing description.

The embodiments of the present application are intended to embrace all such alternatives, modifications and variances which fall within the broad scope of the appended claims. Accordingly, any omissions, modifications, equivalents, substitutions, improvements, etc. made within the spirit and principles of the embodiments of the present application are intended to be within the scope of the present application.

What is claimed is:

1. A method for manufacturing a metal frame chip embedded packaging substrate, the method comprising:
preparing a metal plate;
forming a cavity penetrating the metal plate and a metal frame surrounding the cavity on the metal plate, and selectively partially etching a first surface of the metal frame to form a first groove on the metal frame;
embedding a chip in the cavity so that a patterned side of the chip faces the first surface, and laminating a dielectric layer on a second surface of the metal frame opposite the first surface, wherein the dielectric layer covers a back side of the chip and fills the first groove;
forming a blind hole and a window on the dielectric layer, the blind hole being configured to expose the second surface of the metal frame, and the window being configured to expose the back side of the chip; and
forming a first wiring layer on the first surface and a second wiring layer on the second surface,
wherein the second wiring layer is connected to the back side of the chip through a first conducting post formed by electroplating the window, and is connected to the metal frame through a second conducting post formed by electroplating the blind hole, wherein the first wiring layer is connected to a terminal of the chip.

2. The method of claim 1, wherein a metal thickness of the first groove is less than a thickness of the metal plate.

3. The method of claim 1, wherein the metal thickness of the first groove is 8 microns or more.

4. The method of claim 1, wherein the patterned side of the chip is not covered with the dielectric layer.

5. The method of claim 1, wherein the first wiring layer connected to the terminal of the chip is separately led out through the first groove so as not to be connected to the metal frame.

6. The method of claim 1, wherein the dielectric layer is selected from an Ajinomoto Build-up Film resin and a polypropylene resin.

7. The method of claim 1, wherein the metal plate is a copper plate.
